(19) United States
(12) Patent Application Publication
(10) Pub. No.: US 2005/0236365 A1
(43) Pub. Date: Oct. 27, 2005

(54) Dry etching method and semiconductor device

(75) Inventor: Tsutomu Komatani, Yamanashi (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: EUDYNA DEVICES, INC., Yamanashi (JP)

(21) Appl. No.: 11/115,272

(22) Filed: Apr. 27, 2005

(30) Foreign Application Priority Data
Apr. 27, 2004 (JP) 2004-132124

(51) Int. Cl. H01L 21/00

(52) U.S. Cl. 216/67; 216/41; 438/706; 438/710; 257/79

(57) ABSTRACT

A method of dry etching an etching layer that coats a surface of a GaN based semiconductor layer or a SiC, the method includes performing a first plasma etching to remain a desired thickness of the etching layer, and performing a second plasma etching on a region remained by the first plasma etching with a lower energy than that of the first plasma etching to expose a surface of the GaN based semiconductor layer or the SiC. The method of dry etching of the present invention is capable of suppressing the damage on the GaN based semiconductor layer and thereby achieving the dry etching method of the high selectivity, high anisotropy, low contamination, and low damage. It is thus possible to achieve the GaN based semiconductor device having excellent initial device characteristics and free from degradation due to conduction.

### BACKGROUND OF THE INVENTION

1. Field of the Invention

This invention generally relates to dry etching methods applied to the fabricating processes of semiconductor devices, and more particularly, to a dry etching method that can suppress damage to a semiconductor layer such as GaN, SiC, or the like.

2. Description of the Related Art

The semiconductor device is demanded to be miniaturized, and is accordingly demanded to have a higher breakdown voltage and higher power density. Many studies have been made on a nitride semiconductor such as gallium nitride (GaN), silicone carbide (SiC), and a wide band gap semiconductor such as diamond, because they are considered to be possible solutions. Especially, a nitride semiconductor material was developed as an optical device, yielding a spectacular result in a practical application as a blue light-emitting diode. The nitride semiconductor as represented by GaN has characteristics of the wide band gap and direct transition. Additionally, the nitride semiconductor also has features of a large breakdown voltage, a high saturation drift velocity, excellent heat conductivity, and hetero junction characteristics. The nitride semiconductor is developed as an electronics device having a high power and high frequency.

The dry etching technology is one of essential elemental technologies as a fine processing technology in fabricating the wide band gap semiconductor, and plasma etching is mainly employed. A silicone nitride (SiN) film, for example, is used for an insulating film that coats a GaN based semiconductor layer. A GaN based semiconductor layer is a very hard substrate, and therefore a high-energy plasma etching is performed to etch the SiN film. The SiN film has an etching rate of more than 10 times higher than that of the GaN based semiconductor device. This enables a sufficient over etching, and contributes to improvement in yield ratio. Japanese Patent Application Publication No. 5-3177 (hereinafter referred to as Document 1) describes a high-energy plasma etching for forming an insulating layer that coats a silicon semiconductor layer. The silicon semiconductor layer, which is a lower layer, is easily damaged. Therefore, the high-energy plasma etching is performed at first, and subsequently a low-energy plasma etching is performed. Less damaged plasma etching can be thus achieved.

Generally, silicon has a week interatomic bond, and is susceptible to damage of the plasma etching. So, the plasma etching has to be devised as described in Document 1. However, with respect to the etching process of the SiN film that coats the GaN based semiconductor layer, it is considered unnecessary to shift from the high-energy plasma etching to the low-energy etching as described above. This is because the bonding strength is extremely high between gallium and nitrogen, as compared to the interatomic bonding strength of silicon.

According to the studies of the inventors, however, it becomes obvious for the first time that device characteristics are affected by the damage caused on the GaN based semiconductor layer during the plasma etching.

### SUMMARY OF THE INVENTION

It is a general object of the present invention to provide a semiconductor device having excellent initial device characteristics and free from degradation due to conduction by suppressing the damage on a GaN based semiconductor layer during a plasma etching, although the damage was not conventionally considered to affect the device characteristics.

According to an aspect of the present invention, preferably, there is provided a method of dry etching an etching layer that coats a surface of a GaN based semiconductor layer or a SiC, the method including: performing a first plasma etching to remain a desired thickness of the etching layer; and performing a second plasma etching on a region remained by the first plasma etching with a lower energy than that of the first plasma etching to expose a surface of the GaN based semiconductor layer or the SiC.

According to another aspect of the present invention, preferably, there is provided a semiconductor device including: a GaN semiconductor layer or a SiC; and an etching layer provided on the GaN base semiconductor layer or the SiC, the etching layer has an opening through which a surface of the GaN based semiconductor layer or the SiC is exposed, the opening being defined by a first plasma etching to remain a desired thickness of the etching layer, and a second plasma etching a region remained by the first plasma etching with a lower energy than that of the first plasma etching to expose the surface of the GaN based semiconductor layer or the SiC.

A dry etching method of the present invention includes two etching processes, a first dry etching process and a second dry etching process. In the first dry etching process, the etching layer is etched by a high rate etching (a relatively high-energy etching) in a direction of depth. In the second process, the remaining etching layer is further etched by a low rate etching (relatively a low-energy etching) in the direction of depth. It is thus possible to suppress the damage on the surface of the GaN base semiconductor layer, and thereby realize the GaN based semiconductor device without a degradation of the initial characteristics or degradation due to conduction.

### BRIEF DESCRIPTION OF THE DRAWINGS

Preferred embodiments of the present invention will be described in detail with reference to the following drawings, wherein:

FIGS. 1A through 1C are schematic views illustrating a dry etching method of the present invention;

FIG. 2 is a cross-sectional view of a GaN based HEMT device to be etched by the dry etching method of the present invention and illustrates how a bombardment defect occurs if the conventional dry etching method is employed;

FIGS. 3A through 3C illustrate an example of dry etching processes specifically in accordance with a first embodiment of the present invention;

FIG. 4 shows a compared result of a maximum drain current Ifmax between one device on which two processes of ICP dry etching method has been performed in accordance with the first embodiment of the present invention and the other device on which the conventional reactive ion etching (RIE) has been performed;

FIG. 5 is a cross-sectional view of a GaN based HEMT device to be etched by the dry etching method of the present invention and illustrates how the bombardment defect occurs if the conventional dry etching is performed;

FIGS. 6A through 6C illustrate an example of dry etching processes specifically in accordance with a second embodiment of the present invention;

FIG. 7 show a compared result of the maximum drain current Ifmax between one device on which the two processes of the ICP dry etching method has been performed in accordance with the second embodiment of the present invention and the other device on which the conventional reactive ion etching (RIE) has been performed;

FIG. 8 is a cross-sectional view of a GaN based VCSEL device to be dry etched by the dry etching method of the present invention and illustrates how the bombardment defect occurs if the conventional dry etching is performed;

FIGS. 9A through 9C illustrate a process example of the dry etching method in accordance with a third embodiment of the present invention;

FIG. 10 shows a compared result of the emission intensity (total amount of beam) between one GaN based VCSEL device having the n-type electrode formed on the GaN thick film layer after the two dry etching processes have been performed in accordance with the third embodiment of the present invention and the other device on which the conventional reactive ion etching (RIE) has been performed;

FIG. 11 is a cross-sectional view of a SiC-MESFET device to be dry etched by the dry etching method of the present invention and illustrates how the bombardment defect occurs if the conventional dry etching method is performed; and

FIGS. 12A through 12C illustrate a process example of the dry etching method in accordance with a fourth embodiment of the present invention.

### DESCRIPTION OF THE PREFERRED EMBODIMENTS

A description will now be given, with reference to the accompanying drawings, of embodiments of the present invention.

A dry etching is performed on an etching layer (a layer to be etched) provided adjacently to a GaN based semiconductor crystal layer in accordance with the present invention. A dry etching method of the present invention includes two etching processes, a first dry etching process and a second dry etching process. In the first dry etching process, the etching layer is etched by a high rate etching (a relatively high-energy etching) in a direction of depth with the use of a single fluorine-based gas such as SF₆ or NF₃ or a mixed gas of the fluorine-based gas and any one of chlorine-based gases such as SiCl₄, BCl₃, and Cl₂. The first dry etching process completes so that the etching layer has a remaining portion of a desired thickness by etching. In the second process, the remaining etching layer having the desired thickness is further etched by a low rate etching (relatively a low-energy etching) in the direction of depth. Here, the GaN based semiconductor crystal layer is GaN, InGaN, or AlGaN, for example.

Etching conditions vary, if necessary, depending on the layer, material, or thickness to be etched. For example, an etching gas is introduced into a chamber together with another gas, for example, oxygen, nitrogen, or argon. The pressure inside the chamber is set to 0.1-20 Pa. The substrate temperature is set at 0-150° C.

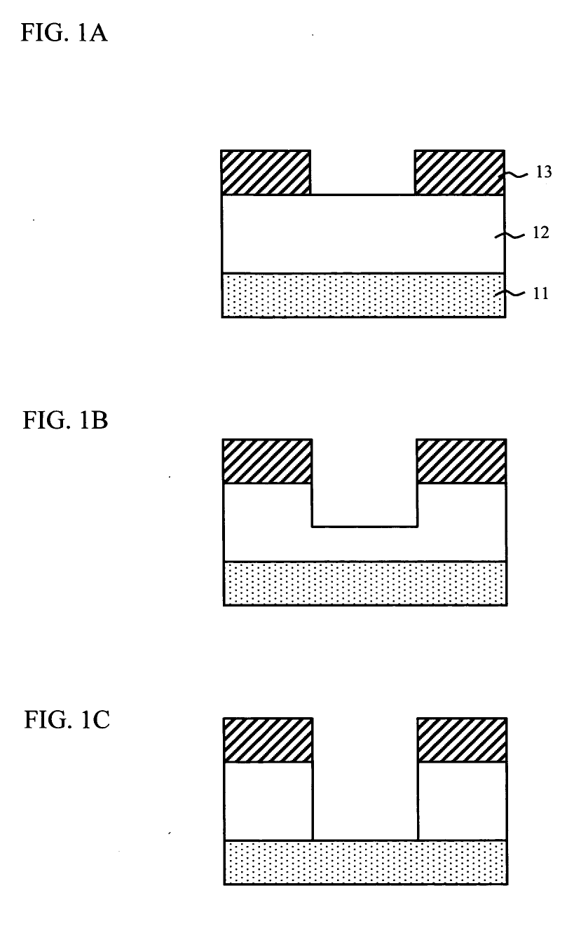

FIGS. 1A through 1C are schematic views illustrating the dry etching method of the present invention. Referring to FIG. 1A, an etching layer 12 is arranged on a surface of a GaN based semiconductor layer 11. A mask 13 partially coats a main surface of the etching layer 12. An open region is provided for dry etching.

In the first dry etching process of the present invention, referring to FIG. 1B, etching ions are bombarded onto the surface of the etching layer 12 from the open region. The energy of the ions etches constituent atoms of the surface of the etching layer 12. A high-speed etching is performed having a high selectivity and anisotropy in the direction of depth. The first dry etching process is achieved to the vicinity of the surface of the GaN based semiconductor layer 11, and is stopped to remain a desired thickness of the etching layer 12. Here, a remote plasma etching is employed such as inductively coupled plasma (ICP) etching or electron cyclotron resonance (ECR) plasma etching. The fluorine-based gas is used for etching the etching layer of SiNx deposited on the GaN based semiconductor layer. The power applied for performing high-density plasma is 300 W, and a bias power is 0.1 W/cm².

Referring to FIG. 1C, the remaining etching layer 12 in the open region, which has not been etched in the first dry etching process, is completely etched in the second dry etching process. The open region covers the main surface of the GaN based semiconductor layer 11. The etching condition in the second dry etching process, namely, the bias power, is determined to make the etching rate lower than that of the first dry etching process. The fluorine-based gas is used for etching as in the first dry etching process, and the power applied for forming high-density plasma is 100 W, and a bias power is 0.03 W/cm².

With the aforementioned two processes of dry etching method, the high selectivity and high anisotropy of the dry etching can be achieved in the first dry etching process of high-speed etching. Low contamination and low damage can be achieved on the GaN based semiconductor layer provided adjacently to the etching layer in the second dry etching process of low-speed etching. It is thus possible to suppress physical damages on a carrier activation region in the device.

Additionally, three or more dry etching processes can be employed so that the etching rates are gradually decreased in a later process. This dry etching method is effective for the remote plasma etching such as ICP etching or ECR plasma etching and other etching methods. That is, each of the first dry etching process and the second dry etching process may comprise two or more steps so that the energies to be used are sequentially lowered in these steps.

It is to be noted that Document 1 discloses one of the methods for realizing the low damage of the dry etching. With the method, contact holes are formed by dry etching with the use of selectivity ratios between the SiO₂-based substance layer and the silicon-based layer provided below the SiO₂-based substance layer. Specifically, two etching processes are employed for dry etching the silicon dioxide-based substance layer. The high-speed etching is performed within a range of the actual thickness (a first process), and a remaining thickness is subsequently etched (a second process).

With the aforementioned etching process, the second process is performed while a compound including sulfur and nitrogen is being deposited on the etching layer. This deposit serves as a buffer for protecting an etching surface from the ion bombardment. In other words, even if the accelerated ions are bombarded onto the etching surface through the deposit, a sponge effect made by the deposit absorbs or alleviates the ion bombardment, and thereby the damage is reduced.

In the above-mentioned etching process, the etching is performed on a crystal, which is originally to be etched, and concurrently on the compound including sulfur and nitrogen provided on the etching layer. Moreover, the compound including sulfur and nitrogen is always being provided on the etching layer, while the etching is being performed. As a result, the etching rate of the second process is lowered. The dry etching method disclosed in Document 1 thus realizes the low damage. However, this effect is obtained by the sponge effect of the deposit provided on the etching layer. The low damage is not realized by the effect of the low-speed dry etching, namely, the low-energy etching ions.

In contrast, the etching ions (plasma) are adjusted to have low energy, and the low-speed etching is performed to etch the etching layer provided adjacently to the GaN based semiconductor layer in accordance with the present invention. The low-speed etching is capable of suppressing the damage on the GaN based semiconductor layer. The low-speed etching process of the present invention is performed on the surface of the semiconductor layer without the deposit as a buffer.

The dry etching method of the present invention can be applied to both selective etching and overall etching.

A description will now be given of the dry etching method of the present invention in further detail.

### First Embodiment

A description will be given of an example in which the dry etching method of the present invention is applied to a SiNx surface protection film layer provided on a GaN based semiconductor layer in accordance with a first embodiment of the present invention.

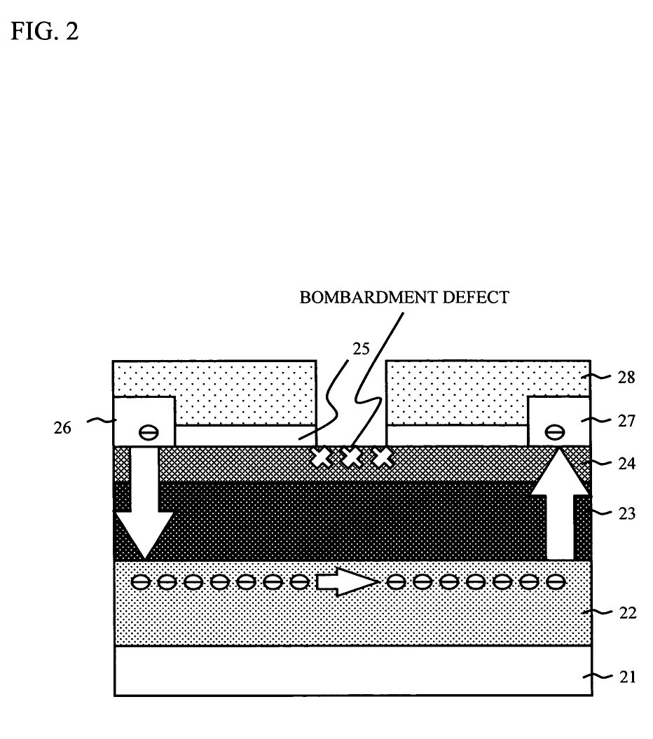

FIG. 2 is a cross-sectional view of a GaN based HEMT device to be etched by the dry etching method of the present invention and illustrates how a bombardment defect occurs if the conventional dry etching method is employed.

This device includes a substrate 21 made of any one of SiC, sapphire, and GaN. An electron traveling layer 22 of GaN, an electron supply layer 23 of n-type AlGaN, and a surface protection thin-film layer 24 of n-type GaN are sequentially provided on the substrate 21. In addition, a protection film 25 of SiNx, a source 26, and a drain 27 are provided on the surface protection thin-film layer 24. A window substance 28 coats the protection film 25, the source 26, and the drain 27. The window substance 28 serves as a mask when the gate is formed by dry etching. The window substance 28 has an open region, namely, a window. The etching ions are bombarded from the open region so as to dry etch the protection film 25 of SiNx. A gate forming region is thus provided and the GaN based HEMT device shown in FIG. 2 is produced.

This device operates, when electrons injected from the source 26 drift through the electron traveling layer 22 to the drain 27. The electron traveling layer 22 arranged below the gate corresponds to a channel region. When the protection film 25 is dry etched with the conventional dry etching method, a physical defect is generated due to the bombardment of the etching ions in a surface region of the surface protection thin-film layer 24 in FIG. 2. This results in a high-resistivity of the surface protection thin-film layer 24. A potential distribution in the channel region is different from the original one, and leads to a current degradation. Therefore, the protection film 25 is partially etched from the open region of the window substance 28 with the above-mentioned two etching processes in accordance with the first embodiment of the present invention. The high selectivity and the high anisotropy can be achieved in the first dry etching process of high-speed etching, and the low contamination and the low damage can be achieved on the surface protection thin-film layer 24 arranged adjacently to the protection film 25 in the second dry etching process of low-speed etching.

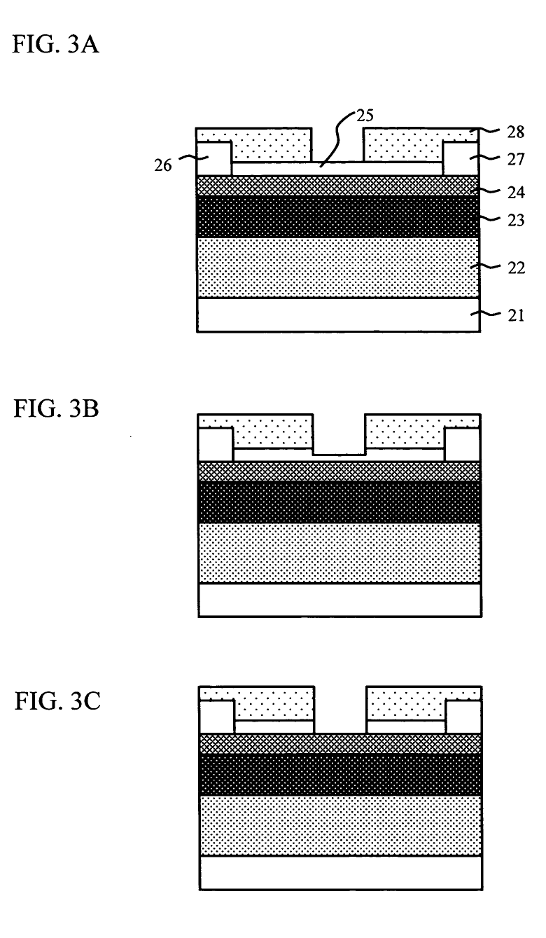

FIGS. 3A through 3C illustrate an example of dry etching processes specifically in accordance with the first embodiment of the present invention. Referring to FIG. 3A, at first, with the fluorine-based gas of SF₆ or NF₃, the window substance 28 having the open region (window) is provided on the protection film 25 of SiNx having a thickness of 100 nm. Referring to FIG. 3B, the etching ions are bombarded from the aforementioned open region so as to etch the protection film 25 in the direction of the depth under the condition that the power applied for forming high-density plasma is 300 W, and a bias power is 0.1 W/cm². The first dry etching process is completed remaining 30 nm of the protection film 25. Referring to FIG. 3C, the power applied for forming high-density plasma is decreased to 100 W, and a bias power is decreased to 0.03 W/cm². The energy of the etching ions is thus decreased, and the second dry etching process is performed so that the remaining protection film 25 in the open region can be etched completely. The surface of the surface protection thin-film layer 24 is exposed and the gate region is thus formed.

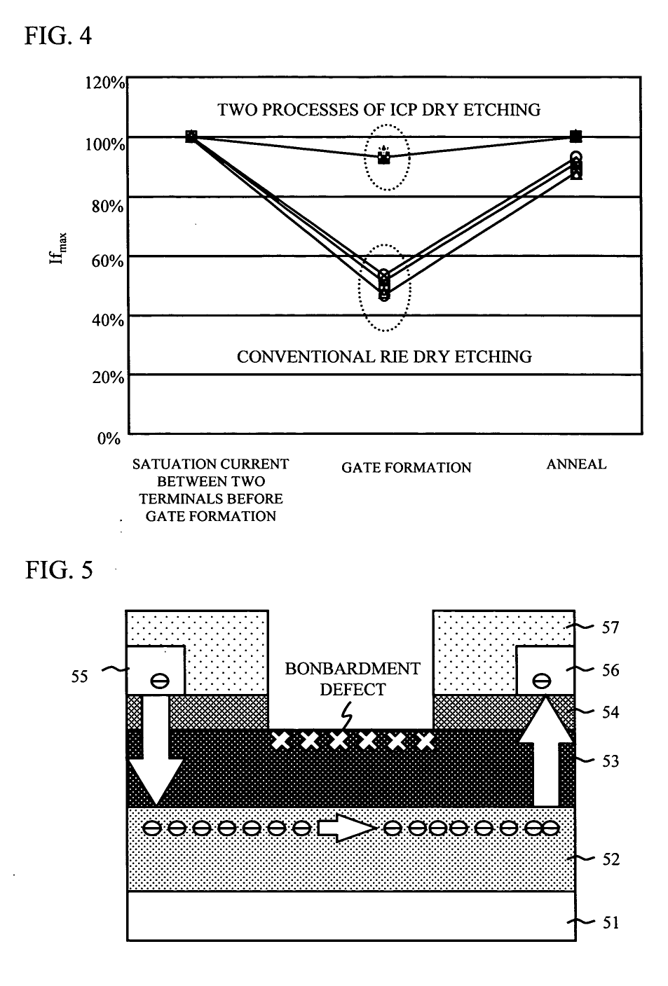

Table 1 and FIG. 4 show a compared result of a maximum drain current Ifmax between one device on which the two processes of the ICP dry etching method have been performed in accordance with the first embodiment of the present invention and the other device on which the conventional reactive ion etching (RIE) has been performed. The drain current was measured under the condition that a voltage between the gate and the source Vgs is 0 V, and the voltage between the drain and the source Vds is 50 V.

TABLE 1

| | Immediately | |
|---|---|---|
| | after gate is | |
| Etching Method | formed | After anneal |
| Present Invention | 91% | 100% |
| Present Invention | 92% | 100% |
| Present Invention | 93% | 100% |
| Present Invention | 93% | 100% |
| Present Invention | 92% | 100% |
| Conventional method | 46% | 89% |
| Conventional method | 51% | 92% |
| Conventional method | 54% | 95% |
| Conventional method | 47% | 88% |
| Conventional method | 52% | 92% |

Here, the drain current Ifmax was measured by saturation current flowing across two terminals before the gate is formed, and is set to 100% as a standard, in the case where the damage does not occur on the surface protection thin-film layer 24. The drain current Ifmax was measured immediately after the gate was formed (no conduction after dry etching) and was measured again after annealing at 350° C.

Data of the “conventional RIE process” in FIG. 4 include respective maximum drain current values Ifmax of before plasma etching (before the gate is formed), after etching (after the gate is formed), and after annealing. Assuming that the maximum drain current values Ifmax before etching is set to 100%, the Ifmax after the gate is formed is decreased to approximately 50%. Even after annealing, the Ifmax is recovered to 90%. This result explains that the damage caused by the plasma etching in the GaN based semiconductor layer adversely affects the device characteristics. The inventors of the present invention have found out the fact for the first time that the damage caused by the plasma etching in the GaN based semiconductor layer adversely affects the device characteristics.

As shown in Table 1 and FIG. 4, with the conventional dry etching method, the device has a large current degradation by approximately 50% immediately after the gate is formed. In contrast, with the dry etching method of the present invention, the device has at most 10% of the current degradation. With respect to the drain current Ifmax after annealing, with the conventional dry etching method, the device can be recovered to approximately 90%. However, with the dry etching method of the present invention, the device can be recovered to 100%.

The dry etching method of the present invention is capable of suppressing the occurrence of the damage on the GaN semiconductor layer when dry etching the SiNx protection film, and thereby is capable of realizing the high selectivity, high anisotropy, low contamination, and low damage. It is thus possible to achieve the GaN based HEMT device without degrading the initial characteristics.

### Second Embodiment

A description will be given of an example in which the dry etching method of the present invention is applied to a GaN surface protection film layer provided on an AlGaN layer.

FIG. 5 is a cross-sectional view of a GaN based HEMT device to be etched by the dry etching method of the present invention and illustrates how the bombardment defect occurs if the conventional dry etching is performed.

This device includes a substrate 51 of any one of SiC, sapphire, and GaN. An electron traveling layer 52 of GaN, and an electron supply layer 53 of n-type AlGaN are sequentially deposited on the substrate 51. In addition, a surface protection thin-film layer 54 of n-type GaN, a source 55, and a drain 56 are provided on the electron supply layer 53. The surface protection thin-film layer 54, the source 55, and the drain 56 are coated by a window substance 57. The window substance 57 serves as a mask when the gate is formed by dry etching. The window substance 57 has an open region, namely, a window. The etching ions are bombarded from the open region so as to dry etch the surface protection thin-film layer 54. A gate forming region is thus provided and the GaN based HEMT device shown in FIG. 2 is produced.

This device operates, when the electrons injected from the source 55 drift through the electron traveling layer 52 to the drain 56. The electron traveling layer 52 arranged below the gate corresponds to the channel region. When the surface protection thin-film layer 54 is dry etched with the conventional dry etching method, the physical defect is generated due to the bombardment of the etching ions in the surface region of the n-type AlGaN electron supply layer 53 in FIG. 5. This results in a high-resistivity of the n-type AlGaN electron supply layer 53. The potential distribution in the channel region is different from the original one, and leads to the current degradation. Therefore, the surface protection thin-film layer 54 is partially etched from the open region of the window substance 57 with the above-mentioned two etching processes in accordance with the second embodiment of the present invention. The high selectivity and the high anisotropy can be achieved in the first dry etching process of high-speed etching, and the low contamination and the low damage can be achieved on the n-type AlGaN electron supply layer 53 arranged adjacently to the surface protection thin-film layer 54 in the second dry etching process of low-speed etching.

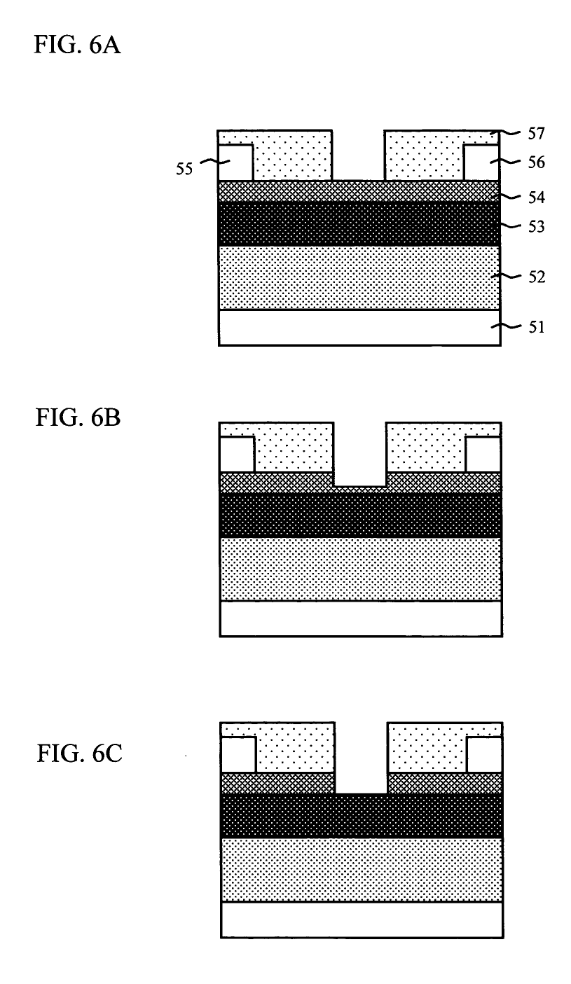

FIGS. 6A through 6C illustrate an example of dry etching processes specifically in accordance with the second embodiment of the present invention. The dry etching is performed with a mixed gas of the fluorine-based gas of either SF₆ or NF₃ and the chlorine-based gas of any one of SiCl₄, BCl₃, and Cl₂.

First, referring to FIG. 6A, the window substance 57 having the open region (window) is provided on the surface protection thin-film layer 54 of GaN having a thickness of 100 nm. Referring to FIG. 6B, the etching ions are bombarded from the aforementioned open region for etching the surface protection thin-film layer 54 in the direction of the depth under the condition that the power applied for forming high-density plasma is 300 W, and a bias power is 0.1 W/cm². The first dry etching process is completed remaining 30 nm of the surface protection thin-film layer 54. Referring to FIG. 6C, the power applied for forming high-density plasma is decreased to 100 W, and a bias power is decreased to 0.03 W/cm². The energy of the etching ions is thus decreased, and the second dry etching process is performed so that the remaining surface protection thin-film layer 54 in the open region can be etched completely. The surface of the n-type AlGaN electron supply layer 53 is thus exposed and the gate region is formed.

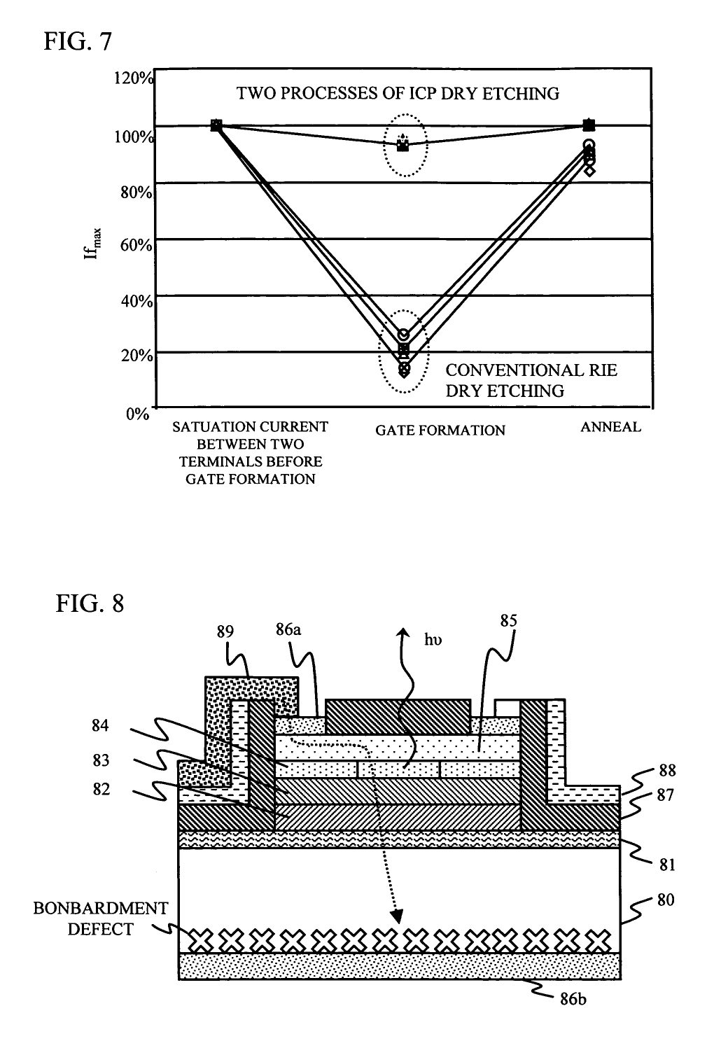

Table 2 and FIG. 7 show a compared result of the maximum drain current Ifmax between one device on which the two processes of the ICP dry etching method have been performed in accordance with the second embodiment of the present invention and the other device on which the conventional reactive ion etching (RIE) has been performed. The drain current is measured under the condition that a voltage between the gate and the source Vgs is 0 V, and a voltage between the drain and the source Vds is 50 V.

TABLE 2

| | Immediately | |
|---|---|---|
| | after gate is | |
| Etching Method | formed | After anneal |
| Present Invention | 92% | 100% |
| Present Invention | 93% | 100% |
| Present Invention | 90% | 100% |
| Present Invention | 93% | 100% |
| Present Invention | 95% | 100% |
| Conventional method | 15% | 90% |
| Conventional method | 22% | 93% |
| Conventional method | 27% | 93% |
| Conventional method | 21% | 92% |
| Conventional method | 14% | 85% |

Here, the drain current Ifmax was measured by saturation current flowing across two terminals before the gate is formed, and is set to 100% as a standard, in the case where the damage does not occur on the n-type AlGaN electron supply layer 53. The drain current Ifmax was measured immediately after the gate was formed (no conduction after dry etching) and was measured again after annealing at 350° C.

According to the result described above, with the conventional dry etching method, the devices have a large current degradation by approximately 14-27% immediately after the gate is formed. In contrast, with the dry etching method of the present invention, the devices have at most 10% of the current degradation. With respect to the drain current Ifmax after annealing, with the conventional dry etching method, the device can be recovered to approximately 90%. However, with the dry etching method of the present invention, the devices can be recovered to 100%.

The dry etching method of the present invention is capable of suppressing the occurrence of the damage on the AlGaN layer so as to dry etch the GaN surface protection film layer and thereby realizing the high selectivity, high anisotropy, low contamination, and low damage. It is thus possible to achieve the GaN HEMT device without degrading the initial characteristics.

### Third Embodiment

A description will be given of an example in which the dry etching method of the present invention is applied to a SiC substrate, which is arranged on a backside of a GaN based vertical cavity surface emitting laser (VCSEL).

FIG. 8 is a cross-sectional view of a GaN VCSEL device to be dry etched by the dry etching method of the present invention and illustrates how the bombardment defect occurs if the conventional dry etching is performed.

A GaN based VCSEL 91 includes a GaN thick-film layer 80 provided on the SiC substrate (not shown), a GaN based buffer layer 81, an n-type GaN layer 82, an InGaN layer 83 having a quantum well structure, an AlGaN layer 84 of a current control layer, a p-type GaN contact layer 85, a p-type ohmic electrode 86a, an n-type ohmic electrode 86b, a SiN protection layer 87, a polyamide film 88, and a wiring material 89.

The p-type ohmic electrode 86a and the n-type ohmic electrode 86b are biased and carriers are injected from the p-type ohmic electrode 86a. The carriers drift through the p-type GaN contact layer 85, the AlGaN layer 84, the InGaN layer 83, and the n-type GaN layer 82, and reach the n-type ohmic electrode 86b provided on the backside of the GaN thick-film layer 80. Here, pairs of electron and hole are recombined based on the quantum effect, a light is emitted from the InGaN layer 83 having the quantum well structure, and the light is emitted upward.

It is to be noted that if the SiC substrate arranged on the backside of the GaN thick film layer 80 is etched and removed with the conventional dry etching method, the physical defect occurs in a back surface region of the crystal due to the bombardment of the etching ions and the GaN thick film layer 80 becomes the high-resistive layer. This results in a degradation of the emission intensity. The SiC substrate provided on the backside of the GaN thick film layer 80 is etched and removed with the two dry etching processes in accordance with the third embodiment of the present invention, and thereby it is possible to decrease the damage in the backside region of the GaN thick film layer 80.

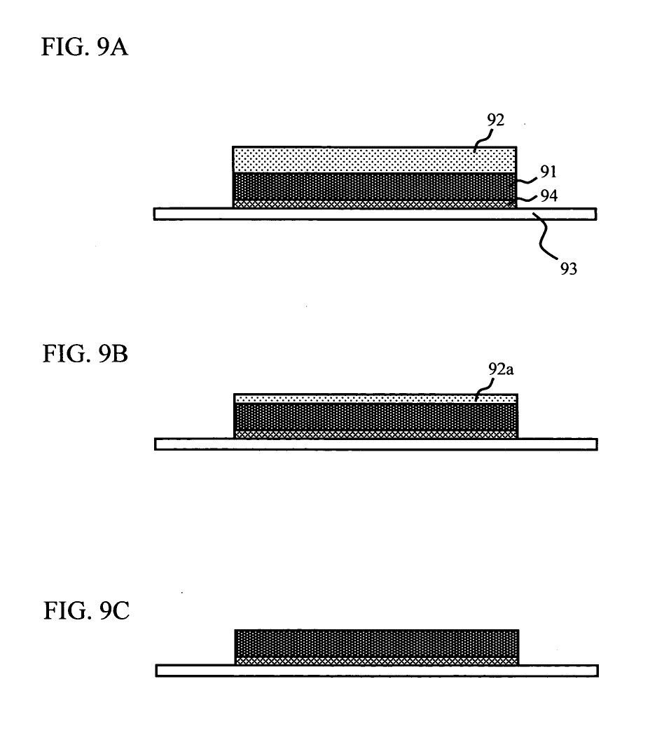

FIGS. 9A through 9C illustrate an example of the dry etching method in accordance with the third embodiment of the present invention. The dry etching is performed with a mixed gas of the fluorine-based gas of either SF₆ or NF₃ and the chlorine-based gas of any one of SiCl₄, BCl₃, and Cl₂.

First, referring to FIG. 9A, a SiC substrate 92 having a thickness of 330 μm is bonded to a glass substrate 93 with a wax 94. The VCSEL 91 shown in FIG. 8 is formed on the SiC substrate 92. The VCSEL 91 and the glass substrate 93 are bonded to face each other, and the SiC substrate 92 only is to be dry etched.

Referring to FIG. 9B, the etching ions are bombarded from the backside of the SiC substrate 92 for etching approximately 300 μm under the condition that the power applied for forming high-density plasma is 600 W, and the bias power is 0.5 W/cm². The first dry etching process is completed remaining 30 μm of a SiC layer 92a. Then, referring to FIG. 9C, the power applied for forming high-density plasma is decreased to 300 W, and the bias power is decreased to 0.1 W/cm². The energy of the etching ions is thus decreased, and the second dry etching process is performed so that the remaining SiC layer 92a can be etched completely.

Table 3 and FIG. 10 show a compared result of the emission intensity (total amount of beam) between one GaN based VCSEL device having the n-type electrode formed on the GaN thick film layer after the two dry etching processes have been performed in accordance with the third embodiment of the present invention and the other device on which the conventional reactive ion etching (RIE) has been performed. A drive current is 70 mA.

TABLE 3

| | Immediately after n-type |
|---|---|
| Etching Method | electrode is formed |
| Present Invention | 99% |
| Present Invention | 99% |
| Present Invention | 99% |
| Present Invention | 99% |
| Conventional method | 89% |
| Conventional method | 91% |
| Conventional method | 92% |
| Conventional method | 90% |

Here, the total amount of beam is set to 100% as a standard, if the damage does not occur on the VCSEL 91. The total amounts of beam of the respective devices were measured.

According to the result described above, with the conventional dry etching method, the devices are degraded in the emission intensity by approximately 10%. In contrast, with the dry etching method in accordance with the third embodiment of the present invention, the devices have at most 1% of the degradation of the emission intenisty.

The dry etching method of the present invention is capable of suppressing the damage on the GaN thick film layer when the SiC substrate is dry etched. It is thus possible to realize the GaN based VCSEL device without degrading the actual emission intensity.

### Fourth Embodiment

A description will be given of an example in which the dry etching method of the present invention is applied to a SiC-MESFET.

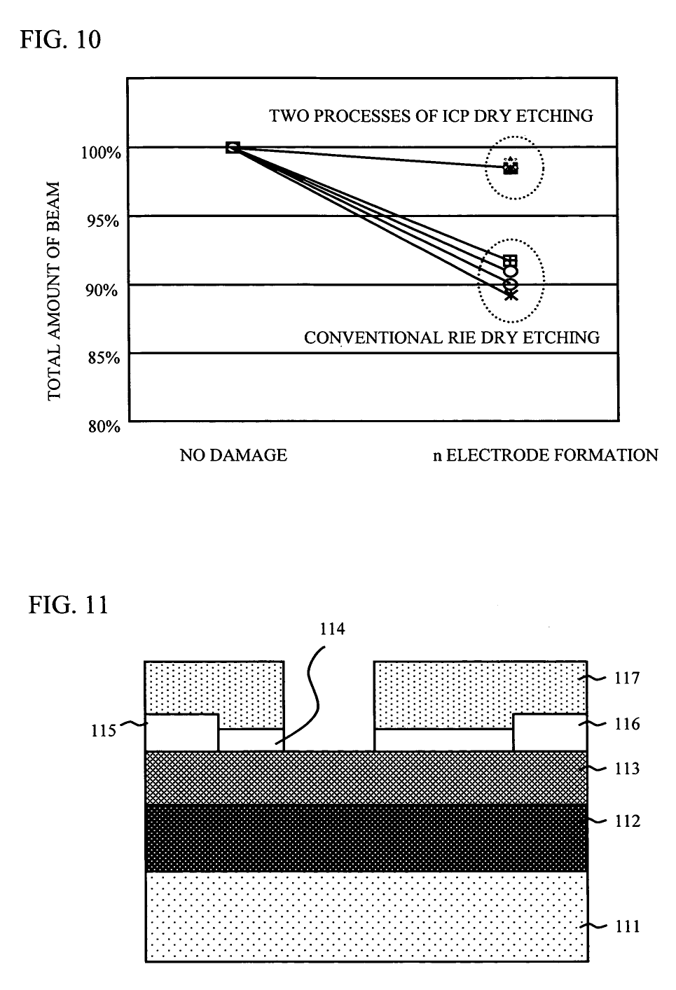

FIG. 11 is a cross-sectional view of a SiC-MESFET device to be dry etched by the dry etching method of the present invention and illustrates how the bombardment defect occurs when the conventional dry etching method is performed.

The SiC-MESFET device includes a semi-insulating SiC substrate 111. A p-type SiC buffer 112 and an n-type SiC channel layer 113 are sequentially deposited on the SiC substrate 111. A protection film 114 of SiO₂ or SiNx, a source 115, and a drain 116 are provided on the SiC channel layer 113. The protection film 114, the source 115, and the drain 116 are coated by a window substance 117. The window substance 117 serves as a mask when the protection film 114 is formed by dry etching. The window substance 117 has an open region, namely, a window. The etching ions are bombarded from the open region so as to dry etch the protection film 114. A gate forming region is provided and the SiC-MESFET device shown in FIG. 11 is thus produced.

It is to be noted that if the protection film 114 is etched with the conventional dry etching method, the physical defect occurs in the crystal and the surface region of the n-type SiC channel layer 113 becomes the high-resistive layer due to the bombardment of the etching ions. The potential distribution in the channel region is different from the original one, and leads to the current degradation. Therefore, the protection film 114 is etched by the above-mentioned two processes of dry etching method of the present invention so as to suppress the occurrence of the bombardment defect on the n-type SiC channel layer.

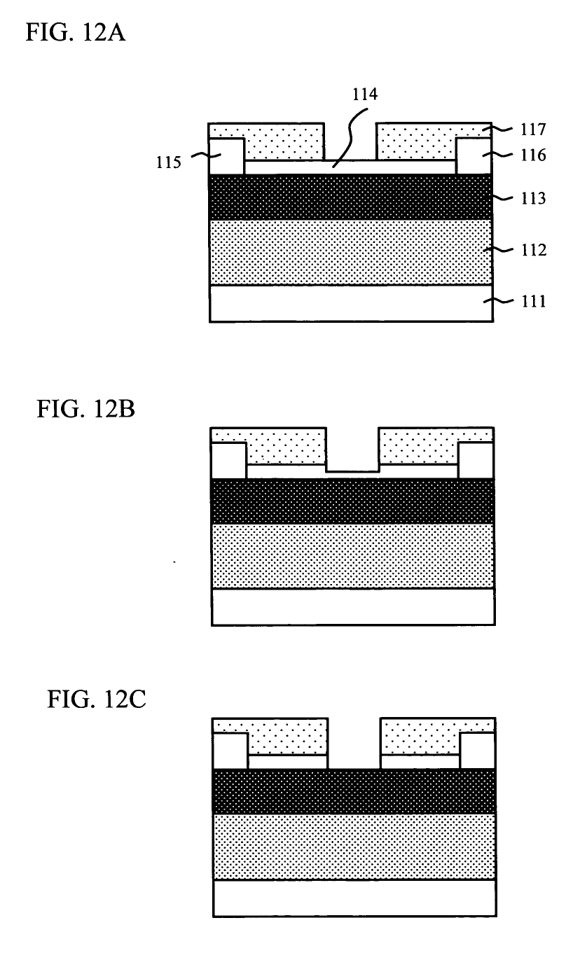

FIGS. 12A through 12C illustrate a process example of the dry etching method in accordance with the fourth embodiment of the present invention. The dry etching is performed with a mixed gas of the fluorine-based gas of either SF₆ or NF₃ and the chlorine-based gas of any one of SiCl₄, BCl₃, and Cl₂.

First, referring to FIG. 12A, the window substance 117 having the open region (the window) is provided on the protection film 114 having a thickness of 100 nm. Referring to FIG. 12B, the etching ions are bombarded from the open region for etching the protection film 114 in the direction of the depth under the condition that the power applied for forming high-density plasma is 300 W, and the bias power is 0.1 W/cm². The first dry etching process is completed remaining 30 nm of the protection film 114. Then, referring to FIG. 12C, the power applied for forming high-density plasma is decreased to 100 W, and the bias power is decreased to 0.03 W/cm². The energy of the etching ions is thus decreased, and the second dry etching process is performed so that the remaining protection film 114 in the open region can be etched completely. The surface of the n-type SiC channel layer 113 is exposed and the gate region is thus formed.

The dry etching method of the present invention is capable of suppressing the occurrence of the damage on the AlGaN layer so as to produce the SIC-MESFET device, and thereby is capable of achieving the dry etching of the high selectivity, high anisotropy, low contamination, and low damage. It is thus possible to achieve the SiC-MESFET device without degrading the initial characteristics.

The dry etching method of the present invention is capable of suppressing the damage on the GaN based semiconductor layer to be occurred by dry etching, and thereby is capable of achieving the dry etching method of the high selectivity, high anisotropy, low contamination, and low damage. It is thus possible to achieve the GaN based semiconductor device having excellent initial device characteristics and free from degradation due to conduction.

The present invention is not limited to the above-mentioned embodiments, and other embodiments, variations and modifications may be made without departing from the scope of the present invention.

The present invention is based on Japanese Patent Application No. 2004-132124 filed on Apr. 27, 2004, the entire disclosure of which is hereby incorporated by reference.

1. A method of dry etching an etching layer that coats a surface of a GaN based semiconductor layer or a SiC, the method comprising:
performing a first plasma etching to remain a desired thickness of the etching layer; and
performing a second plasma etching on a region remained by the first plasma etching with a lower energy than that of the first plasma etching to expose a surface of the GaN based semiconductor layer or the sic.

2. The method as claimed in claim 1, wherein at least one of the first plasma etching and the second plasma etching comprises multiple steps of performing plasma etching and energies to be used are sequentially lowered in the multiple steps.

3. The method as claimed in claim 1, wherein the GaN based semiconductor layer comprises any one of Gan, InGan, and AlGaN.

4. The method as claimed in claim 1, wherein the dry etching uses a single fluorine-based gas or a mixed gas, the fluorine-based gas being SF₆ or NF₃, the mixed gas being one of the fluorine-based gases mixed with one of chlorine-based gases of SiCl₄, BCl₃, and Cl₂.

5. The method as claimed in claim 1, wherein the dry etching is performed by a remote plasma etching of either inductively coupled plasma (ICP) etching or electron cyclotron resonance (ECR) plasma etching.

6. The method as claimed in claim 1, wherein a mask is provided on the etching layer in advance to perform the first plasma etching and the second plasma etching on an open region of the mask.

7. The method as claimed in claim 1, wherein a whole surface of the etching layer is etched by performing the first plasma etching and the second plasma etching.

8. The method as claimed in claim 1, wherein the GaN based semiconductor layer forms a carrier traveling region of HEMT, MESFET, or VCSEL.

9. A semiconductor device comprising:
a GaN based semiconductor layer or a SiC; and
an etching layer provided on the GaN based semiconductor layer or the SiC,
the etching layer has an opening through which a surface of the GaN based semiconductor layer or the SiC is exposed,
the opening being defined by a first plasma etching to remain a desired thickness of the etching layer, and a second plasma etching a region remained by the first plasma etching with a lower energy than that of the first plasma etching to expose the surface of the GaN based semiconductor layer or the SiC.
